(19) United States
(12) Patent Application Publication
(10) Pub. No.: US 2018/0323741 A1
(43) Pub. Date: Nov. 8, 2018

(54) SYSTEMS FOR SOLAR POWER GENERATION AND METHODS OF CONSTRUCTING THE SAME

(71) Applicant: ENERDYNAMIC HYBRID TECHNOLOGIES CORP., Welland (CA)

(72) Inventor: Jeremy Rejean TISI, Welland (CA)

(21) Appl. No.: 15/772,417

(22) PCT Filed: Nov. 3, 2016
(86) PCT No.: PCT/CA2016/051282

§ 371 Date: Apr. 30, 2018

Related U.S. Application Data
(60) Provisional application No. 62/250,228, filed on Nov. 3, 2015.

(51) Int. Cl. H02S 20/23; H01L 31/048; H02S 40/34

(52) U.S. Cl. CPC H02S 20/23; H02S 40/34; H01L 31/048

(57) ABSTRACT

There is disclosed herein a system for generation of solar power, the system including a plurality of supports each disposed at least partially in a vertical direction; at least one panel adapted to be supported by the supports. The panel includes a substrate layer that is at least partially upwardly directed when the panel is supported by the supports. An insulating layer is adjacent and at least partially beneath the substrate layer. An interior layer is adjacent and at least partially beneath the insulating layer. Solar cell modules are positioned on the panel adjacent the substrate layer, and module includes wafer cells. The wafer cells are interconnected by a plurality of ribbons, wherein the wafer cells and ribbons are substantially encapsulated by a layer of protective material.

### FIELD

The present disclosure relates to systems for solar power generation, including those provided integral to structures, and the constituent elements of such systems.

### BACKGROUND

Solar panels/modules are often utilized for power generation in remote environments wherein the climate is suitable for use of such systems, and there is limited (although not necessarily non-existent) related infrastructure. Such environments include, for example, environments otherwise requiring ease of use in view of added expenses stemming from specialized staffing and maintenance requirements.

Generally, installation and maintenance of solar power generation systems requires specialized staff, who must be present at and transported to the installation location. While installation is typically a single time occurrence, maintenance concerns can be significant and ongoing. Diminished power generation is, of course, a primary concern, and can result from many different failure or sub-optimal performance scenarios, such as the compromising of solar panel wafer integrity and/or cracking of glass componentry. The latter scenario can result in the need to replace an entire module, which is expensive, time consuming and has the potential to introduce significant delays, particularly in remote environments.

Further, even with the involvement of trained installation personnel, damage to parts (especially solar module/panel portions) is common during installation. This is due in part to the susceptibility of such components to damage that substantially impairs their function, as well as due to the rigours of installation in environments featuring harsh or extreme weather conditions. Similar concerns arise vis-á-vis maintenance, as damage during use, or due to weather or other factors can result in needs to engage costly repair personnel, or to replace systems or components thereof.

It is generally preferable for solar modules to be placed on generally upwardly facing portions of structures (e.g., rooves) to maximize duration of available sunlight. Solar modules are typically attached to structures that are already in place, and are not integral thereto. More specifically, structures are not typically built with a view to easy or effective inclusion of solar power generation componentry and, even if they are, such designs do not include or contemplate solar power generation componentry provided with structural components in a substantially “ready to build” configuration.

Generally, such componentry in also not provided in a modular manner, wherein components may be readily repaired or replaced without highly specialized expertise. Indeed, prior art systems require bringing to bear specialized expertise to refit or complete the installation such that it may operate in an optimal manner. This can add significant costs in most any implementation environment, particularly ones that are harsh from a climatic perspective, or are remotely located.

There is thus a need for structures having integrated solar power generation and implementation and structural componentry, which facilitates quick assembly, disassembly, repair and movement. Further, it is advantageous to provide such items with minimal weight to not require re-engineering of any related structures (which would necessitate engagement of sophisticated and potentially costly personnel) in certain instances. Still further, it is advantageous to provide such solar and structural componentry in a manner such that risk of fire is minimized without substantially sacrificing performance, or substantially complicating construction and assembly logistics.

In this regard, the susceptibility to breakage of solar panels (from handling; weather: e.g., hail and the like; damage during assembling when coupling to surface of structural elements, etc.) is generally quite high such that there is a need to also provide solar modules wherein the modules are adhered or mounted on a substrate resistant to the elements, and suitable for integral construction with structural elements. This is to alleviate concerns such as cell cracking, which can result in loss of poor generation potential.

There do not exist ready for construction, modular structures with substantially integral solar generation and capture componentry. Efforts at producing ready for construction structures (in a manner akin to ready to assemble furniture and other products) have failed as many employ heavier structural componentry to alleviate strength concerns but neglect to consider, for example, the negative impact of weight in terms of modularity, assembly, structural concerns and mobility.

There is a need for solar modules and related structures that may be constructed, deconstructed and/or repaired in a modular manner, without need to replace large portions of the structure or componentry when faced with minor damage or necessary structural changes.

### BRIEF SUMMARY

There is disclosed herein improved apparatuses, systems and methods of providing solar power generation modules, structures incorporating the same, and methods of constructing the foregoing.

There is herein disclosed a system for generation of solar power, including a plurality of supports each disposed at least partially in a vertical direction; at least one panel adapted to be supported by the supports, wherein the panel comprises: a substrate layer, wherein the substrate layer is at least partially upwardly directed when the panel is supported by the supports; an insulating layer adjacent and at least partially beneath the substrate layer; and, an interior layer adjacent and at least partially beneath the insulating layer; a plurality of solar cell modules positioned on the panel substantially adjacent the substrate layer, wherein each of the modules comprises a plurality of wafer cells, wherein the wafer cells are interconnected by a plurality of ribbons, and, wherein the wafer cells and ribbons are substantially encapsulated by a layer of protective material.

In another disclosed embodiment, the layer of protective material is adhered to the substrate layer.

In another disclosed embodiment, the system also includes electrical hardware integral to the panel, including at least one junction box operatively connected to the solar module and adapted to act as a conduit therefrom.

In another disclosed embodiment, the at least one panel comprises a plurality of panels.

In another disclosed embodiment, adjacent ones of the supports are affixed to one another via one or more of adhesives, bolts, and other fasteners.

In another disclosed embodiment, the substrate layer comprises a multi-layer twill and mat comprising a fiber-glass form impregnated with resin, and wherein the resin is fire-retardant.

There is also herein disclosed a panel for use with a solar power generation system, the panel including: a substrate layer; an insulating layer adjacent and at least partially beneath the substrate layer; and an interior layer adjacent and at least partially beneath the insulating layer; a plurality of solar cell modules positioned on the panel substantially adjacent the substrate layer, wherein each of the modules comprises a plurality of wafer cells, wherein the wafer cells are interconnected by a plurality of ribbons, and wherein the wherein the wafer cells and ribbons are substantially encapsulated by a layer of protective material.

In another disclosed embodiment, a layer of protective material is adhered to the substrate layer of the panel.

In another disclosed embodiment, the panel also includes at least on junction box operatively connected to the solar modules and adapted to act as a conduit therefrom.

In another disclosed embodiment, the junction box is embedded within the panel.

In another disclosed embodiment, the substrate layer comprises a multi-layer twill and mat comprising a fiber-glass form impregnated with resin, and wherein the resin is fire-retardant.

There is also herein disclosed a method of constructing a panel for use with a solar power system, the method comprising the steps of: stringing together and operationally connecting a plurality of solar cells; positioning the cells for encapsulation in a protective layer; encapsulating the cells in a protective layer; adhering a substrate layer to an intermediate layer; and adhering the protective layer to the substrate layer.

### BRIEF DESCRIPTION OF THE DRAWINGS

FIG. 1 is a left side perspective view of a system;

FIG. 2 is a right side perspective view of the system shown in FIG. 1;

FIG. 3A is a top view of a solar module;

FIG. 3B is a side view of the solar module shown in FIG. 3A;

FIG. 4 is a perspective view of the interior of a further embodiment of a system;

FIG. 5 is a perspective view of a substrate;

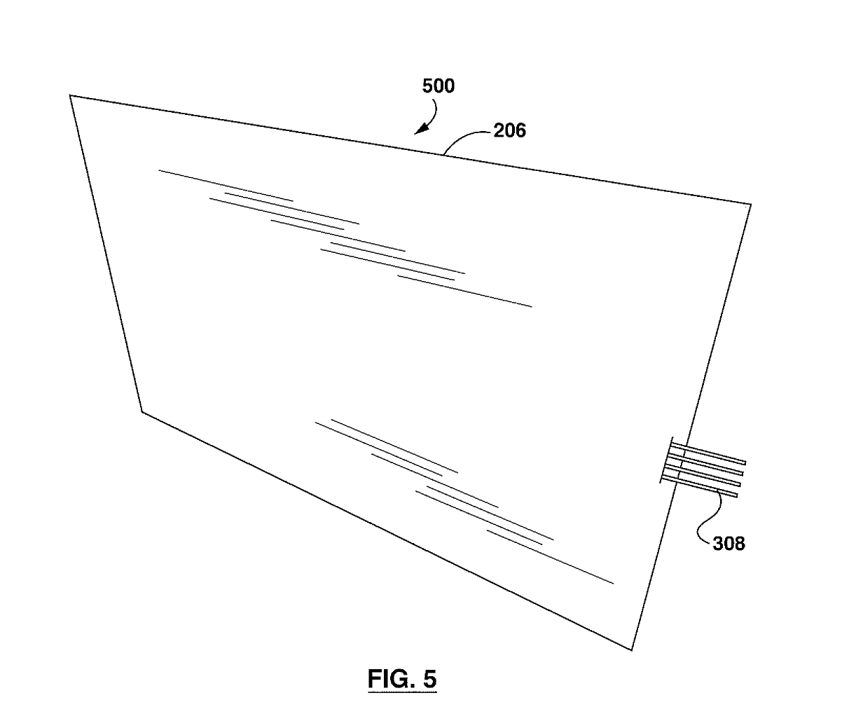

FIG. 6 is a top view of a panel with solar modules attached thereto;

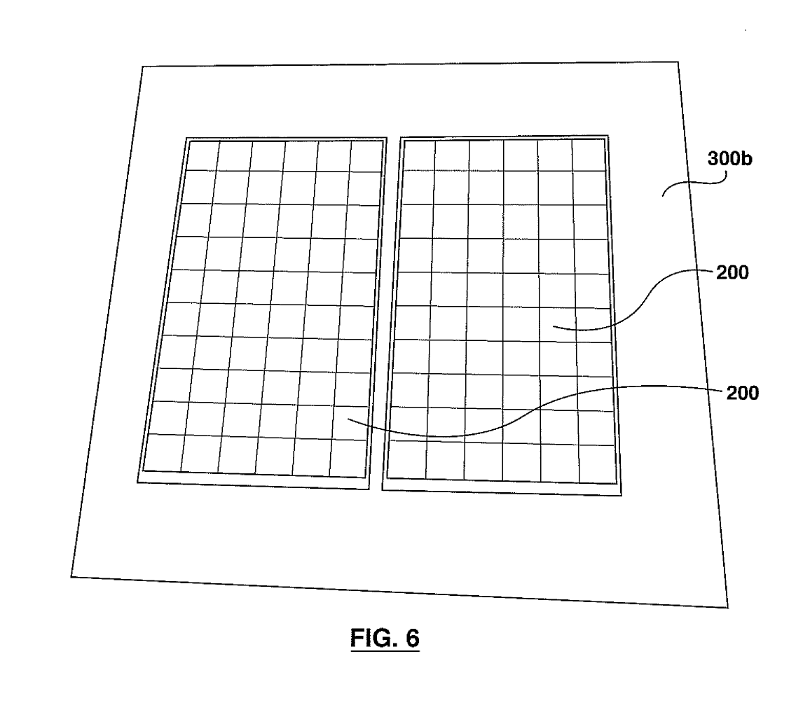

FIG. 7 is a side view of the panel shown in FIG. 6;

FIG. 8 is a perspective view from above of a roof panel with a plurality of solar modules and related hardware installed thereon;

FIG. 9 is a perspective view from below the roof panel shown in FIG. 8;

FIG. 10 is an exploded view of the system as shown in FIG. 2; and,

FIG. 11 is a block diagram showing the steps in a method disclosed herein.

### DETAILED DESCRIPTION

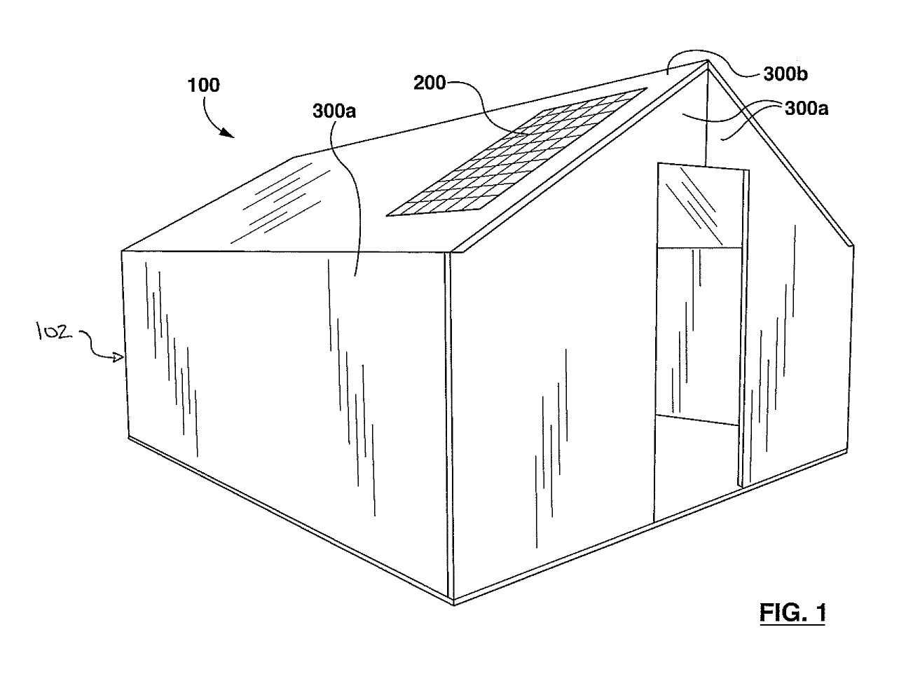

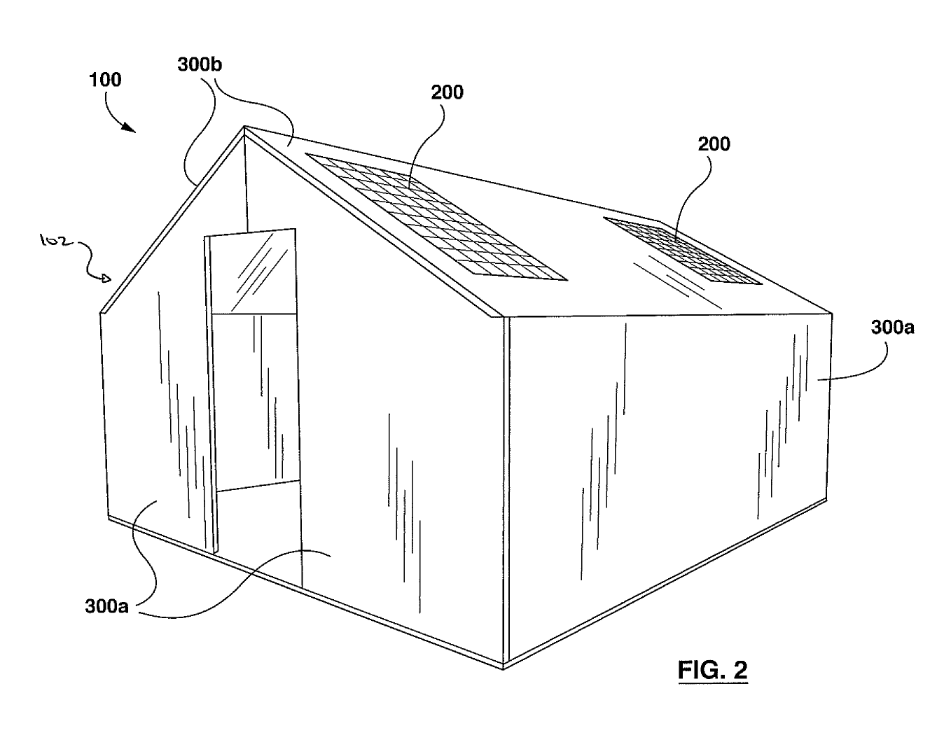

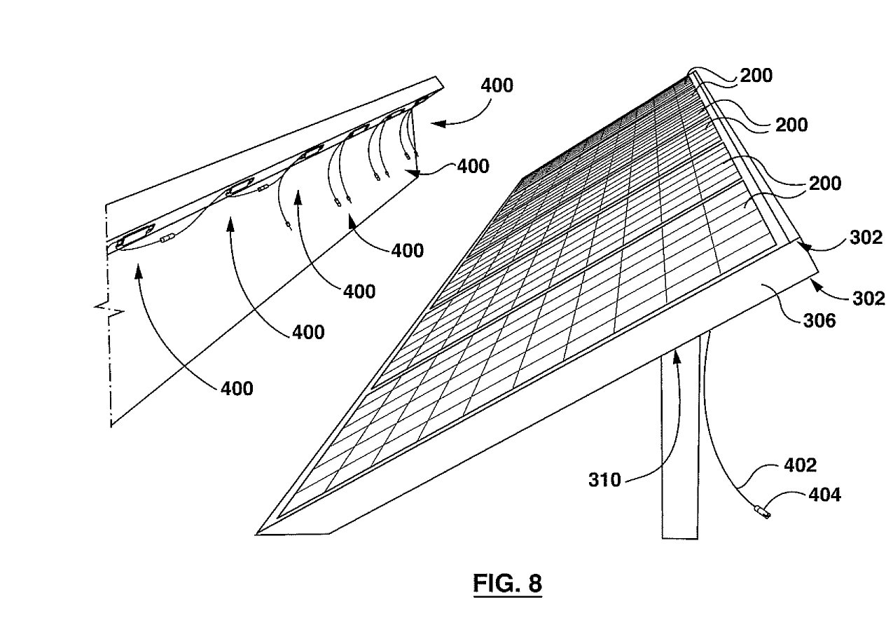

Looking to the Figures, there is a provided a system 100 which comprises, when shown in an assembled configuration, as in FIGS. 1 and 2, a structure 102. The structure 102 comprises a plurality of supports 300a (alternatively referred to herein as supporting panels) disposed at least partially in a vertical direction. This disposition may be altered, as one role of such supports 300a is to support the assembled structure, such that changes may be made to the extent that such role is still being fulfilled. There will also be provided at least one panel 300b operationally positioned substantially atop the supporting panels 300a. While the panels 300b are shown as being positioned directly adjacent the supporting panels 300a, there may be provided additional supporting or attaching components (not shown) to provide spacing between the upwardly directed panels 300b and the supporting panels 300a. The generally upward facing direction of the panels 300b is advantageous vis-à-vis positioning to capture maximum time in the path of available sunlight; however, geographic considerations and design constraints (e.g., available footprint area for the building, locations, sizes and architecture of adjacent or nearby structures; need for drainage of rainwater or other fluid(s) from the top of the system 100, etc.) may dictate the particular angle of disposition (shown as θ in the Figures) as between panel types 300a and 300b. Further, the identification of the upwardly directed panels 300b is not intended to convey that such panels must be provided in a horizontal or even substantially horizontal orientation. The supporting panels 300a may be affixed to one another and to the upwardly directed panel(s) 300b via one or more of adhesives, bolts, and other fasteners—see, for example, the adhesive 310 shown in FIG. 8. While the structures 102 are shown in the Figures as having a substantially rectangular footprint and angled roof, other designs may be employed. For example, rounded or partially rounded structures 102 may be used, and adjacent structures 102 may be adjusted.

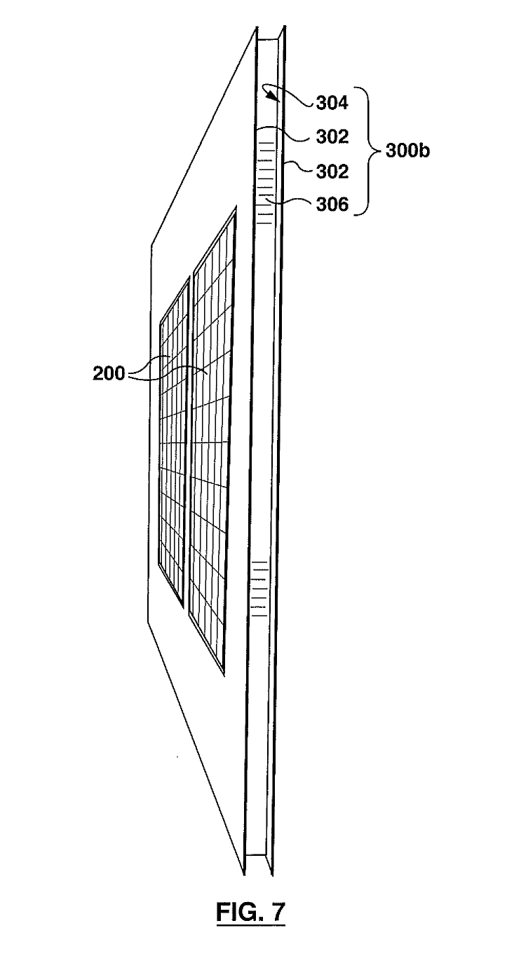

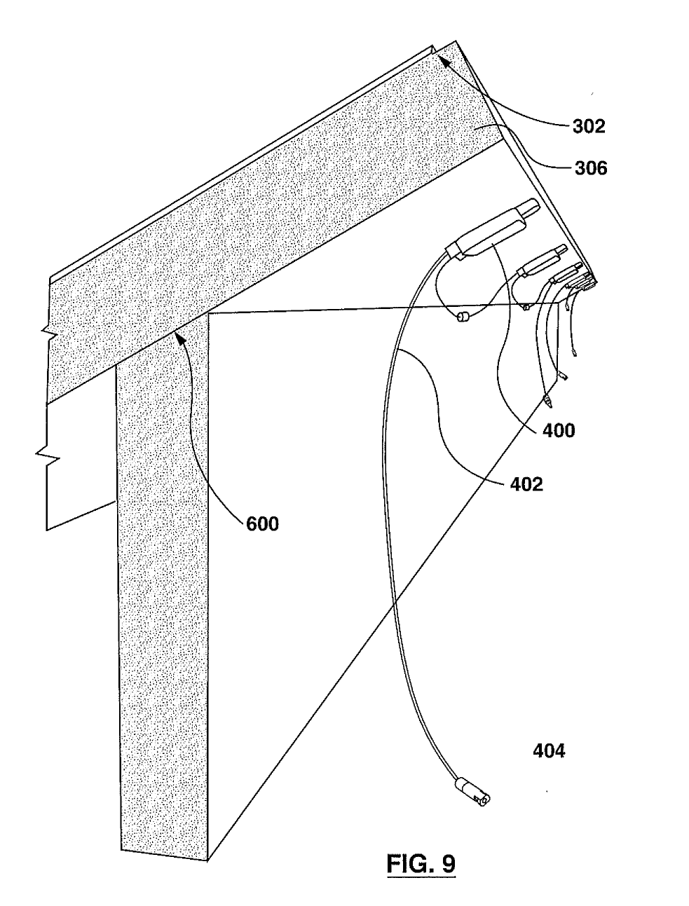

As shown in FIGS. 7 through 9, the panels 300b preferably comprise a substrate layer 302 that is operationally directed substantially upward, as well as an insulating and intermediate layer 306 adjacent and operationally beneath the substrate layer 302. In some embodiments, the panels 300b may be positioned in a vertical orientation but such that they will receive available sunlight in the implementation location (e.g.) where locations and sizes of neighboring structures otherwise block the sun. The substrate layer 302 may preferably be composed of, for example, materials resistant to moisture and weather, and suitable for adhering to or forming with the intermediate layer 306. The substrate layer 302 may still further preferably be comprised of a fire-resistant material. In some embodiments, and to provide strength, adhesion and durability, a multi-layer twill and mat combination of a fiber-glass impregnated with fire retardant resin is preferred. The fire retardant property of the substrate layer 302 serves to increase the safety and durability of the system 100. This is of particularly significant concern in implementation environments wherein extremely high temperatures and arid conditions are the norm. Use of such materials is also advantageous in terms of minimizing support and panel weight while monitoring strength.

The intermediate layer 306 may be composed of any material suitable for providing structural integrity, adequate protection from the elements, and, preferably, being of sufficiently low weight. Examples of suitable materials include: sandwich panels consisting of EPS (Expanded Poly Styrene), XPS (Extruded Poly Styrene), Expanded Poly Urethane, Honey Comb Cores, and the like. The panels 300b may also include an interior layer 304 adjacent to and beneath (when considering relative operational orientation) the insulating layer 306. The interior layer 304 may also, to provide structural strength, adhesion and durability, be composed of a multi-layer twill and/or mat combination of fiber-glass impregnated with fire retardant resin. Using such materials further enhances the stability and operational safety of the structure 102. The low profile construction of the panels 300b is less susceptible to damage from wind. In traditional solar the modules are bolted to racking which is bolted to a structure at points, the racking requires the strength and durability to hold modules in place during high winds without ripping them off. The racking also must withstand the lifting force which also strains the structure. A module built as part of the structure does not experience this force in the same way.

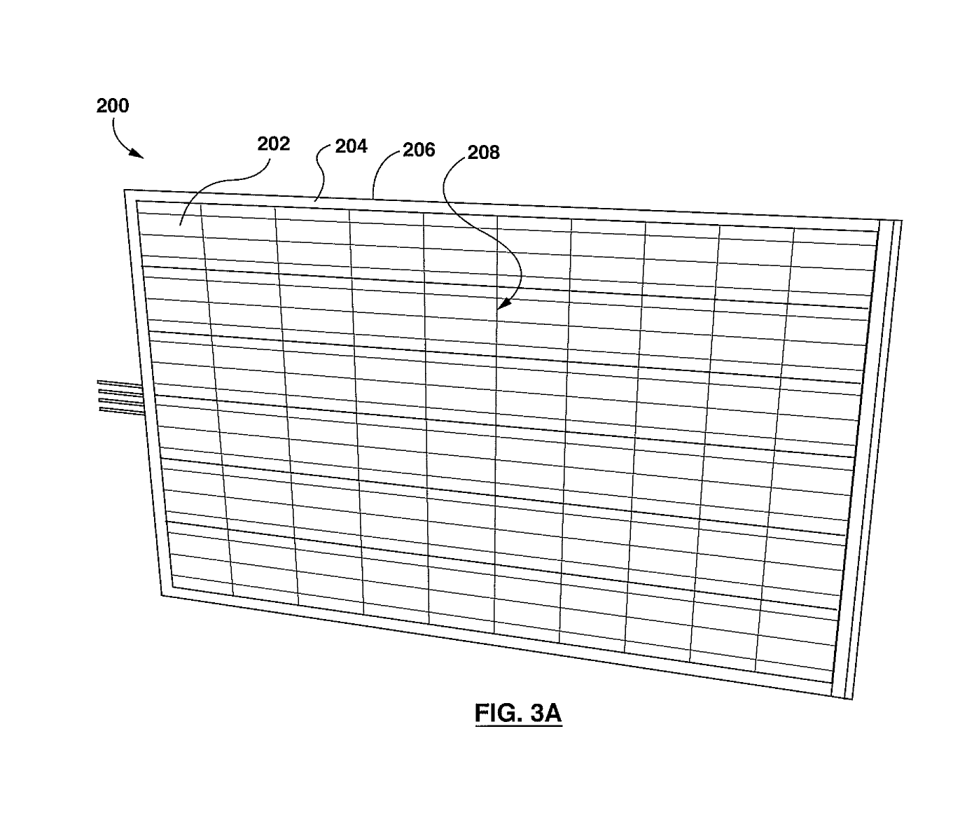

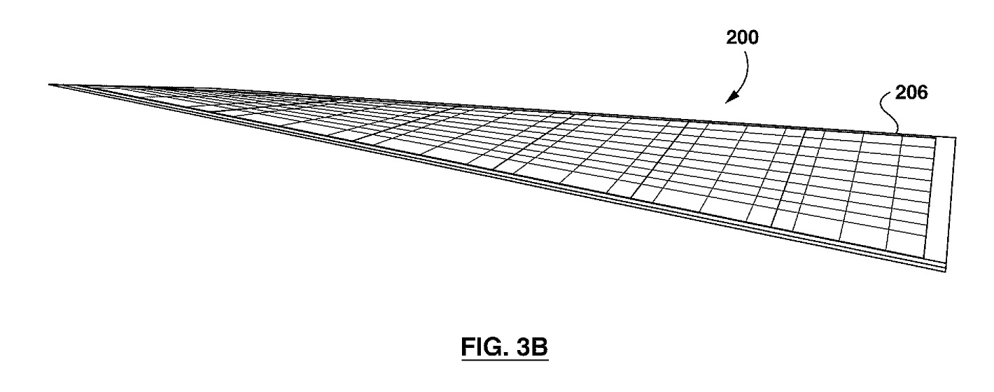

On each of the upwardly directed panels 300b there may be provided a plurality of solar cell modules 200, as shown in FIGS. 1, 2, 7-8 and 10. Each of the modules 200 may include a plurality of wafer cells 202, which may preferably be interconnected by way of a plurality of ribbons 204 comprised of, for example, tin and lead, for conducting electrical current produced by individual wafers (a variation of this interconnection can be done in a cage form which increases durability as well as conducting electrical current, as discussed below). Each of the wafer cells 202, and the modules 200, is substantially encapsulated by a layer of protective material 206 (with the resultant assembled structure shown as 200 in the drawings; for example, FIGS. 3A and 3B). This material 206 may, in some embodiments, be comprised of, for example, ethylene-vinyl acetate (“EVA”) or the like, including, as further examples, polyethylene-vinyl acetate (“PEVA”), polyolefin elastomer (polymer) (“POE”), polyester based acetate (“PYE”) and fluoropolymer. The cells 202 themselves are interconnected by way of ribbons (not shown in detail), with the generally modular configuration thereof being helpful in minimizing the impact of damage to any particular one(s) of the cells 202, in terms of overall functionality and performance. The connected and encapsulated wafer cells 202 may, in some embodiments, be laminated onto the substrate layer 302 via adherence by way of, for example, a superstrate such as PET (not shown in detail). The substrate layer 302 forms a strengthening and weather resistant barrier, allowing for attachment of the cells 202 thereto in, for example, the manner described above.

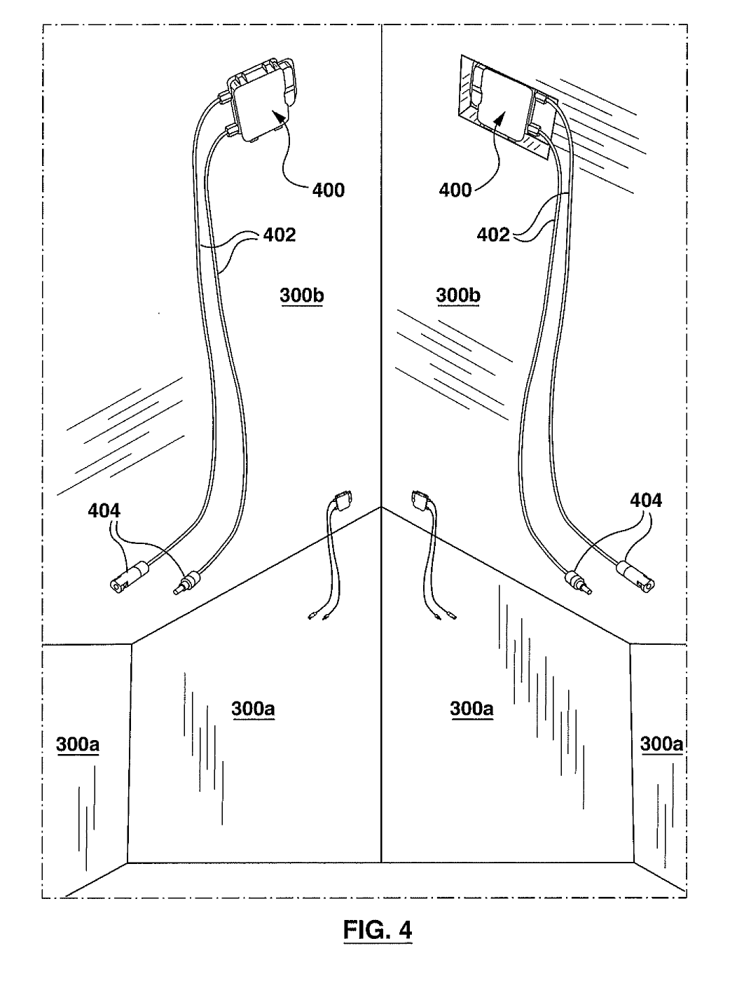

Electrical hardware including, for example, a plurality of junction boxes 400 may be integrated to the panels 300b, as shown in FIGS. 4, 8 and 9. Integration of such componentry greatly increases ease of installation and decreases the level of expertise needed to complete such installation. The electrical hardware 400 is operatively connected to the solar modules 200, and adapted to act as a conduit therefrom, as will be appreciated by one skilled in the art. In some instances, the boxes 400 may be provided recessed into the panels 300b, as shown in the right hand side of FIG. 4. Related componentry may include, but is not limited to, wires 402 for connection to electrical infrastructure to be used in or in association with the structure 102. Various type of electrical componentry could be included in systems 100 and panels 300b herein disclosed, to cater to the needs of a given application, and consistent with the modular nature of systems 100 and panels 300b herein disclosed. Again, integration of junction boxes 400 into the structure 100 (i.e., the panels 300b) facilitates the, essentially, ready to build nature of the panels 300a and 300b that may be provided on their own or as components of apparatuses and systems 100 resulting in assembled structures such as those shown and described herein. Panels 300b may also be provided for integration and use with other solar power generation systems. In some instances, panels 300b may be positioned adjacent or affixed to existing structures to add or enhance over generation capabilities.

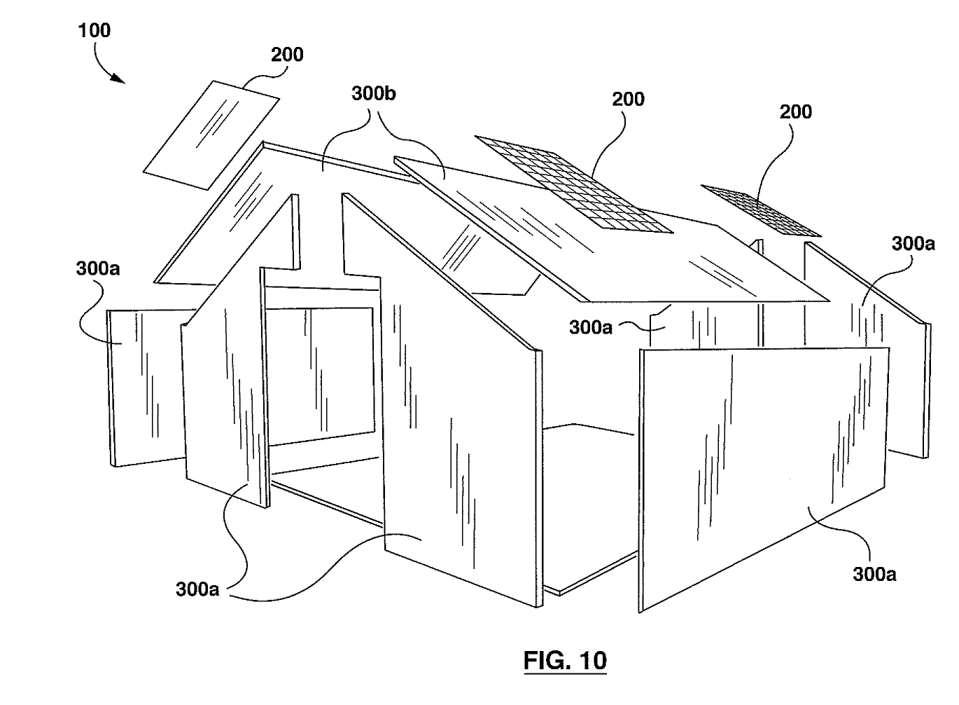

Systems 100 herein disclosed can be pre-assembled and easily transported from location to location. Similarly, and as will be appreciated from consideration of FIG. 10, component supports 300a and panels 300b may be provided in an unassembled configuration. Given the relatively low weight of such components, and the generally integrated or contained nature of their constituent elements, structures may be assembled by end users with suitable instructions. Further, some assembled structure may be suitable for movement from location to location. This facilitates re-use and rapid redeployment (e.g., at multiple disaster areas, military encampments, or in other situations). These advantages extend still further to include not only relatively ready disassembly and movement, but also to repair. This is either by way of replacement of individual or multiple components (e.g., panels 300b/supports 300a, and other embodiments) in a modular manner, or as needed basis, or the addition of further componentry to an assembled system 100.

As mentioned above, potential power loss is a significant problem in respect of solar systems. Unlike known systems, systems 100 provided in the manner herein disclosed address such problems in multiple ways. For example, changes in bussing material (e.g., using materials of a mesh-type) will generally allow for minor cracking of cell 200 parts with little to no loss of power generation and transmission. Further, the encapsulation and modular nature of the cells 202 serves to protect individual elements and minimize the impact of damage to any single one. Still further, the use of such materials can be additionally advantageous in terms of its flexibility maximizing exposed surface area (e.g., as may be appreciated from the curvature of the exemplary panel 200 shown from the side in FIG. 3B (which may, in some embodiment, allow for the harnessing of more power per square meter of structural footprint).

The panels 300b and supports 300a, may be provided in a wide variety of geometries and configurations to allow for assembly of resulting structures 100 of desired shapes and sizes. Further, composing the panels of relatively light materials further allows for use thereof in refitting existing structures without likelihood of impaired physical integrity or risk of failure due to increased load.

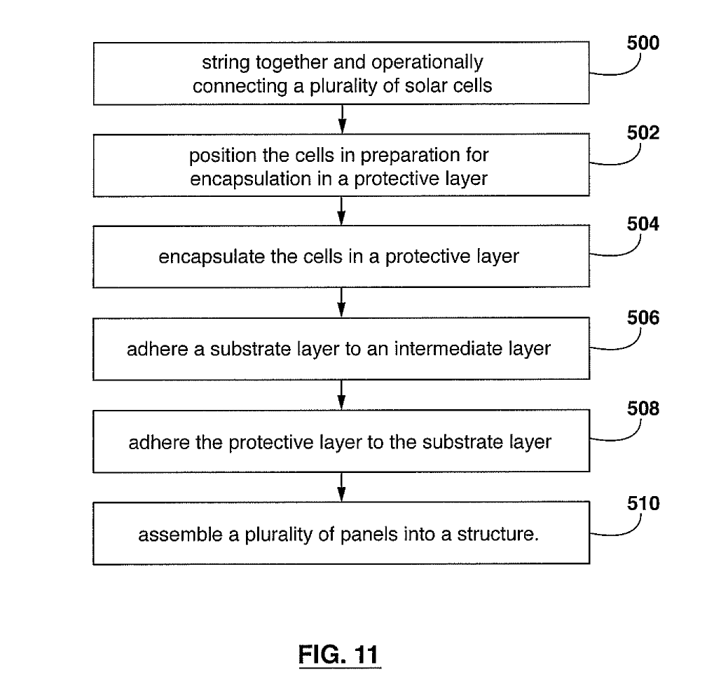

Also disclosed are methods 500 of constructing panels 300b and systems 100 as disclosed herein. While discussed below in an overall manner, it will be appreciated that selected steps could be used to create individual ones of such items. Further, while a single method 500 is outlined below, and detailed in FIG. 11, no rights are disclaimed in any other methods of constructing the systems 100, panels 300b herein disclosed.

An exemplary method of assembling systems 100 including at least one integral solar module 200, includes the following steps:

502—stringing together and operationally connecting a plurality of wafer-type solar cells;

504—positioning the cells in preparation for encapsulation in a protective layer;

506—encapsulating the cells in a protective layer;

508—adhering a substrate layer to an intermediate layer to form a panel; and,

510—adhering the protective layer to the substrate layer,

In some embodiments, the methods 500 may also include assembling a plurality of panels into a structure. The step of positioning includes precise measurements to ensure proper spacing preventing electrical shorting between individual wafers and strings of wafers. The step of encapsulating includes comprises the use of lamination equipment with formulated temperature and pressure settings. The step of adhering includes the use of temperature controls, adhesives and pressure

In some embodiments, the cells 200 may be soldered together into strings of, for example, 10 to 12, and/or further soldered to others to form, for example, an overall circuit of 60 or 72 cells (although different numbers may be employed in different embodiments). Such a circuit of cells may then be placed onto a sheet of the substrate after encapsulation in EVA as herein described.

In some embodiments, the steps of positioning the cells 200 and encapsulating them may further comprise providing a PET insulator that may preferably be placed between bus bars to avoid shorting any assembled circuits. Further sheets of EVA may be placed thereupon and, thereupon, a sheet of PET. After this basic assembly takes place the resulting module 200 may be laminated/encapsulated as described herein. In some instances, edges of the module 200 may be sealed with silicone (or similar sealants) prior to adherence to the substrate layer 302. After such adherence, the junction box 400 may be connected.

While certain types of cells are preferred, others may be used; however, changes may impact the overall power production of the finished system. Needs particular to a given application and other design constraints (e.g., weight, cost) may dictate such choices and accommodations. For example, glass and materials having similar properties are not preferred for use is disclosed systems as such materials would tend to increase weight and decrease durability of the overall system.

As one skilled in the art will appreciate, variations in cell configuration may alter voltage and current properties; however, these design considerations would generally be addressed at the stage of panel composition and construction, to provide panels 300 suitable to a given application.

A number of the disclosed features of the systems 100 are given to be of great use in environments where existing power infrastructure has been impaired (e.g., disaster areas) or is not in place (e.g., remote, underdeveloped areas). Further, and while certain advantageous properties herein disclosed are particularly significant when considering use in remote environments, or those in which ease of assembly, takedown and reassembly is a paramount concern, it will be appreciated that these properties are nevertheless advantageous in other environments, including but not limited to, urban environments and residential communities of varying population densities.

While various embodiments in accordance with the principles disclosed herein have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

It will be understood that the principal features of this disclosure can be employed in various embodiments without departing from the scope of the disclosure. Those skilled in the art will recognize, or be able to ascertain using no more than routine experimentation, numerous equivalents to the specific procedures described herein. Such equivalents are considered to be within the scope of this disclosure and are covered by the claims.

Additionally, the section headings herein are provided as organizational cues. These headings shall not limit or characterize the invention(s) set out in any claims that may issue from this disclosure. Specifically and by way of example, although the headings refer to a “Field of Invention,” such claims should not be limited by the language under this heading to describe the so-called technical field. Further, a description of technology in the “Background of the Invention” section is not to be construed as an admission that technology is prior art to any invention(s) in this disclosure. Neither is the “Summary” to be considered a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, un-recited elements or method steps.

All of the apparatuses, systems and methods disclosed and/or claimed herein can be made and executed without undue experimentation in light of the present disclosure. While the compositions and methods of this disclosure have been described in terms of preferred embodiments, it will be apparent to those of skill in the art that variations may be applied to the compositions and/or methods and in the steps or in the sequence of steps of the method described herein without departing from the concept, spirit and scope of the disclosure. All such similar substitutes and modifications apparent to those skilled in the art are deemed to be within the spirit, scope and concept of this disclosure.

1. A system for generation of solar power, the system comprising:
a. a plurality of supports each disposed at least partially in a vertical direction;
b. at least one panel adapted to be supported by the supports, wherein the panel comprises:
i. a substrate layer, wherein the substrate layer is at least partially upwardly directed when the panel is supported by the supports;
ii. an insulating layer adjacent and at least partially beneath the substrate layer; and
iii. an interior layer adjacent and at least partially beneath the insulating layer;
c. a plurality of solar cell modules positioned on the panel substantially adjacent the substrate layer,
wherein each of the modules comprises a plurality of wafer cells,
wherein the wafer cells are interconnected by a plurality of ribbons, and,
wherein the wafer cells and ribbons are substantially encapsulated by a layer of protective material.

2. The system according to claim 1, wherein the layer of protective material is adhered to the substrate layer.

3. The system according to claim 1, further comprising:
electrical hardware integral to the panel, and comprising at least one junction box operatively connected to the solar module and adapted to act as a conduit therefrom.

4. The system according to claim 1, wherein the at least one panel comprises a plurality of panels.

5. The system according to claim 1, wherein adjacent ones of the supports are affixed to one another via one or more of adhesives, bolts, and other fasteners.

6. The system according to claim 1, wherein the substrate layer comprises a multi-layer twill and mat comprising a fiber-glass form impregnated with resin, and wherein the resin is fire-retardant.

7. A panel for use with a solar power generation system, the panel comprising:
a substrate layer;
an insulating layer adjacent and at least partially beneath the substrate layer; and
an interior layer adjacent and at least partially beneath the insulating layer;
a plurality of solar cell modules positioned on the panel substantially adjacent the substrate layer, wherein each of the modules comprises a plurality of wafer cells, wherein the wafer cells are interconnected by a plurality of ribbons, and wherein the wherein the wafer cells and ribbons are substantially encapsulated by a layer of protective material.

8. The panel according to claim 7, wherein a layer of protective material is adhered to the substrate layer.

9. The panel according to claim 7, further comprising at least on junction box operatively connected to the solar modules and adapted to act as a conduit therefrom.

10. The panel according to claim 9, wherein the junction box is embedded within the panel.

11. The panel according to claim 7, wherein the substrate layer comprises a multi-layer twill and mat comprising a fiber-glass form impregnated with resin, and wherein the resin is fire-retardant

12. A method of constructing a panel for use with a solar power system, the method comprising the steps of:
(i) stringing together and operationally connecting a plurality of solar cells;
(ii) positioning the cells for encapsulation in a protective layer;
(iii) encapsulating the cells in a protective layer;
(iv) adhering a substrate layer to an intermediate layer; and
(v) adhering the protective layer to the substrate layer.

13. The method according to claim 12, further comprising assembling a plurality of the panels into a structure.
